(19) United States
(12) Patent Application Publication
(10) Pub. No.: US 2025/0323120 A1
(43) Pub. Date: Oct. 16, 2025

(54) SEMICONDUCTOR PACKAGE WITH LOCALIZED HOT SPOT COOLING SOLUTION AND METHOD FOR FORMING THE SAME

(71) Applicant: Taiwan Semiconductor Manufacturing Company, Ltd., Hsinchu (TW)

(72) Inventors: Hsin Ting Lin, Hsinchu County (TW); Lipu Kris Chuang, Hsinchu City (TW); Chihting Lai, Hsinchu City (TW)

(21) Appl. No.: 19/243,855

(22) Filed: Jun. 20, 2025

Related U.S. Application Data
(63) Continuation of application No. 18/655,561, filed on May 6, 2024.
(60) Provisional application No. 63/621,565, filed on Jan. 16, 2024.

(51) Int. Cl. H01L 23/38; G02B 6/42; H01L 25/16; H10N 10/01

(52) U.S. Cl. CPC H01L 23/38; G02B 6/4271; H01L 25/167; H10N 10/01

(57) ABSTRACT

A semiconductor package and the method for forming the same are provided. The semiconductor package includes an oxide layer, and a waveguide and a photonic component located on a first side of the oxide layer. The semiconductor package also includes a heater element adjacent to the photonic component and configured to provide thermal energy to the photonic component. The semiconductor package also includes a redistribution structure located on a second side of the oxide layer opposite the first side. The redistribution structure includes a plurality of dielectric layers and conductive features in the dielectric layers. In addition, the semiconductor package includes a thermoelectric cooling device embedded in the dielectric layers of the redistribution structure and located directly below the photonic component.

### REFERENCE TO RELATED APPLICATIONS

This Application is a Continuation of U.S. application Ser. No. 18/655,561, filed on May 6, 2024, which claims the benefit of U.S. Provisional Application No. 63/621,565, filed on Jan. 16, 2024. The contents of the above-referenced Patent Applications are hereby incorporated by reference in their entirety.

### BACKGROUND

Electrical signaling and processing is one technique for the transmission and processing of signals. In addition, optical signaling and processing has been used in an increasing number of applications in recent years, particularly through the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as for processing and control. Accordingly, devices that integrate optical components and electrical components are produced to convert between optical signals and electrical signals, as well as for the processing of optical signals and electrical signals. Packages (also referred to as photonic packages) may thus include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a photonic package with a localized hot spot occurring within one or more dielectric layers, in accordance with some embodiments.

FIG. 2 is a cross-sectional view of a photonic package with an embedded thermoelectric cooling (TEC) device in one or more dielectric layers, in accordance with some embodiments.

FIG. 3 is a schematic view showing the working principle of the thermoelectric cooling device shown in FIG. 2, in accordance with some embodiments.

FIG. 4 is a plan view (e.g., a top-down view) showing the arrangement of a heater element, a photonic component (e.g., a modulator), and the thermoelectric cooling device shown in FIG. 2, in accordance with some embodiments.

FIGS. 5A to 5M illustrate cross-sectional views of intermediate steps of forming the photonic package shown in FIG. 2, in accordance with some embodiments.

FIG. 6 is a cross-sectional view of a photonic package with an embedded thermoelectric cooling device in one or more dielectric layers, in accordance with some embodiments.

FIG. 7 is a plan view (e.g., a top-down view) showing the arrangement of a heater element, a photonic component (e.g., a modulator), a heat spreader, and the thermoelectric cooling device shown in FIG. 6, in accordance with some embodiments.

FIG. 8 is a cross-sectional view of a photonic package with an embedded thermoelectric cooling device in one or more dielectric layers, in accordance with some embodiments.

FIG. 9 is a cross-sectional view of a photonic package with an embedded thermoelectric cooling device in one or more dielectric layers, in accordance with some embodiments.

FIG. 10 is a plan view (e.g., a top-down view) showing the arrangement of a heater element, a photonic component (e.g., a modulator), a heat spreader, and the thermoelectric cooling device shown in FIG. 9, in accordance with some embodiments.

FIG. 11 is a cross-sectional view of a semiconductor package that includes the photonic package shown in FIG. 2 mounted on a printed circuit board (PCB), in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, so that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

A semiconductor package (e.g., a photonic package) and the method for forming the same are provided in accordance with some embodiments of the present disclosure. In some embodiments, a heater element is integrated into the photonic package to deliver high power energy to a silicon photonic component (e.g., a modulator) to maintain the modulator operating at the desired high temperature. Inevitably, however, the thermal energy generated by the heater element is also transferred the heated modulator to nearby components (e.g., some dielectric layers underneath the modulator), thereby creating a localized hot spot in the region of the dielectric layers located directly below the modulator. In accordance with some embodiments, a thermoelectric cooling (TEC) device is provided (e.g., embedded) in the dielectric layers to remove and dissipate heat from the dielectric layers, thereby reducing thermal risks to the dielectric layers. As a result, the reliability of the dielectric layers and the entire package is improved.

The Embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

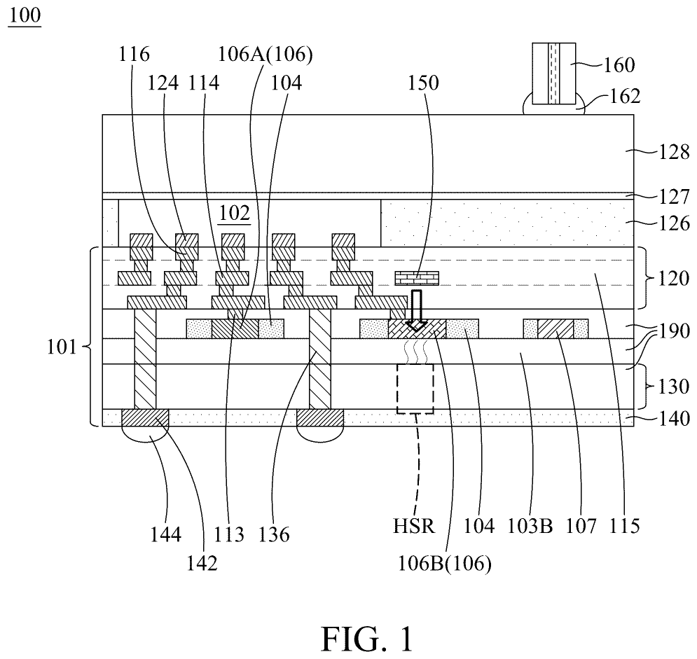

FIG. 1 is a cross-sectional view of a photonic package 100, in accordance with some embodiments. In some cases, the photonic package 100 may be part of a semiconductor package or another structure. The photonic package 100 may provide an input/output (I/O) interface between optical signals and electrical signals in a semiconductor package. In some embodiments, the photonic package 100 provides an optical network for signal communication between components (e.g., photonic components, integrated circuits, couplings to external fibers, etc.) within the photonic package 100. In some cases, the photonic package 100 may be considered an “optical engine.” In the example of FIG. 1, the photonic package 100 includes an electronic die 102 attached (e.g., bonded) to a photonic die 101.

The electronic die 102 may be, for example, a semiconductor device, die, or chip that communicates with the photonic die 101 using electrical signals. In the illustrated embodiments, the electronic die 102 does not receive, transmit, or process optical signals. In the discussion herein, the term “electronic die” is used to distinguish it from the term “photonic die” (e.g., 101), which refers to a die that can receive, transmit, or process optical signals, such as converting an optical signal into an electric signal, or vice versa. Besides optical signals, the photonic die 101 may also transmit, receive, or process electrical signals. One electronic die 102 is shown in the example of FIG. 1, but the photonic package 100 may include two or more electronic dies 102 in other embodiments. In some cases, multiple electronic dies 102 may be incorporated into a single photonic package 100 in order to reduce processing cost. The electronic die 102 includes die connectors 124, which may be, for example, conductive pads, conductive pillars, or the like. The electronic die 102 is bonded to the topmost conductive features (e.g., die connectors 116) of the redistribution structure 120 (sometimes also referred to as the interconnect structure 120) of the photonic die 101 via the die connectors 124.

The electronic die 102 may include integrated circuits for interfacing with photonic components 106 of the photonic die 101. The electronic die 102 may include circuits for controlling the operation of the photonic components 106. For example, the electronic die 102 may include controllers, drivers, transimpedance amplifiers, the like, or combinations thereof. The electronic die 102 may also include a central processing unit (CPU), in some embodiments. In some embodiments, the electronic die 102 includes circuits for processing electrical signals received from a photonic component 106. The electronic die 102 may control high-frequency signaling of a photonic component according to electrical signals (digital or analog) received from another device or die, in some embodiments. In some embodiments, the electronic die 102 may be an electronic integrated circuit (EIC) or the like that provides Serializer/Deserializer (SerDes) functionality. In this manner, the electronic die 102 may act as part of an I/O interface between optical signals and electrical signals within the photonic package 100. In some embodiments, the photonic packages 100 described herein could be considered system-on-chip (SoC) or system-on-integrated-circuit (SoIC) devices.

In some embodiments, a dielectric layer 126 is formed around the electronic die 102 over the redistribution structure 120 of the photonic die 101. The dielectric material 126 may be a gap-fill material, which may include silicon oxide, silicon nitride, a polymer, the like, or a combination thereof. In some embodiments, the dielectric material 126 may be a material (e.g., silicon oxide) that is substantially transparent to light at wavelengths suitable for transmitting optical signals or optical power between a photonic structure (e.g., optical coupler 107) of the photonic die 101 and an external optical fiber 160 attached to the photonic package 100.

In some embodiments, an optional support 128 is attached to the top surfaces of the electronic die 102 and the dielectric layer 126 using an adhesive layer 127, in accordance with some embodiments. The support 128 is a rigid structure to provide structural or mechanical stability of the package. One or more external optical fibers 160 may be attached (e.g., secured) to the support 128 using a glue 162, which may be an adhesive, an optical glue, or the like, to provide optical signals or optical power to the photonic die 101.

Still referring to FIG. 1, the photonic die 101 includes one or more dielectric layers 109, conductive features (e.g., conductive lines (not shown for simplicity) and vias 136) formed in the dielectric layers 109, and various photonic devices formed in the dielectric layers 109, such as waveguides 104, photonic components 106, and optical couplers 107. In some cases, the waveguides 104, the photonic components 106, and the optical couplers 107 may be collectively referred to as a “photonic layer” or as a “photonic integrated circuit (PIC).”

In some embodiments, the waveguides 104 are silicon waveguides formed by patterning a silicon layer. One waveguide 104 or multiple waveguides 104 may be patterned from the silicon layer. If multiple waveguides 104 are formed, the multiple waveguides 104 may be individual separate waveguides 104 or connected as a single continuous structure. In some embodiments, one or more of the waveguides 104 form a continuous loop.

The photonic components 106 may be integrated with the waveguides 104, and may be formed with the waveguides 104. The photonic components 106 may be optically coupled to the waveguides 104 to interact with optical signals within the waveguides 104. The photonic components 106 may include, for example, photonic devices such as photodetectors 106A and modulators 106B in some embodiments. For example, a photodetector 106A may be optically coupled to the waveguides 104 to detect optical signals within the waveguides 104 and generate electrical signals corresponding to the optical signals. A modulator 106B may be optically coupled to the waveguides 104 to receive electrical signals and generate corresponding optical signals within the waveguides 104 by modulating optical power within the waveguides 104. In this manner, the photonic components 106 facilitate the input/output (I/O) of optical signals to and from the waveguides 104. In some cases, the photonic components 106 comprise silicon material and may therefore also be referred to herein as silicon photonic components 106. In other embodiments, the photonic components 106 may include other active or passive components, such as laser diodes, optical signal splitters, or other types of photonic structures or devices. Optical power may be provided to the waveguides 104 by, for example, optical fibers 160 coupled to an external light source (not shown). Contacts 113 (e.g., copper vias) are formed to electrically couple the photonic components 106 to the redistribution structure 120 of the photonic die 101.

One or more optical couplers 107 may be integrated with the waveguides 104, and may be formed with the waveguides 104. Each optical coupler 107 (e.g., a grating coupler or an edge coupler) is a photonic structure that allows optical signals and/or optical power to be transferred between the corresponding waveguide 104 and a photonic component such as an optical fiber 160 or a waveguide of another photonic system.

FIG. 1 also shows the redistribution structure 120 (also referred to herein as a first redistribution structure 120) of the photonic die 101 located over the dielectric layers 109. The redistribution structure 120 includes one or more dielectric layers 115 and conductive features 114 (e.g., conductive lines and vias) formed in the dielectric layers 115, and may provide interconnections and electrical routing. Die connectors 116 (e.g., copper pillars, copper pads, or the like) of the photonic die 101 are formed at the upper surface of the photonic die 101 (e.g., the topmost surface of the redistribution structure 120) and are electrically coupled to the conductive features 114 of the redistribution structure 120.

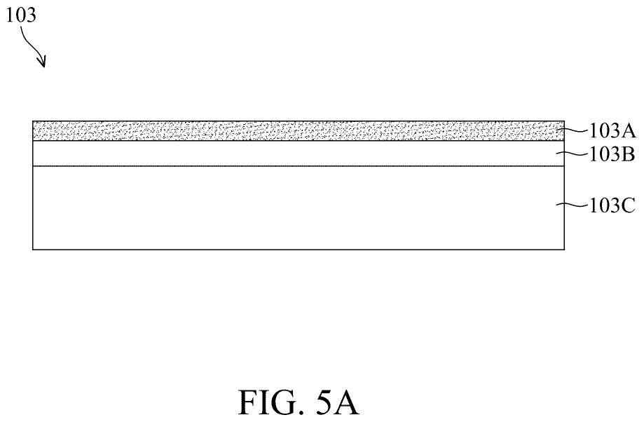

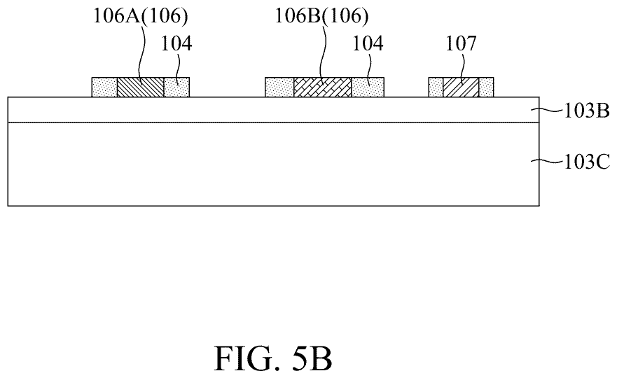

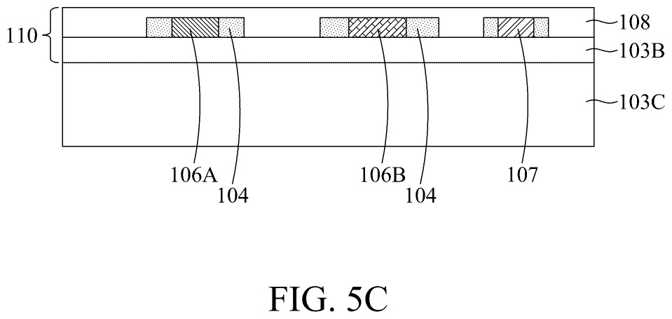

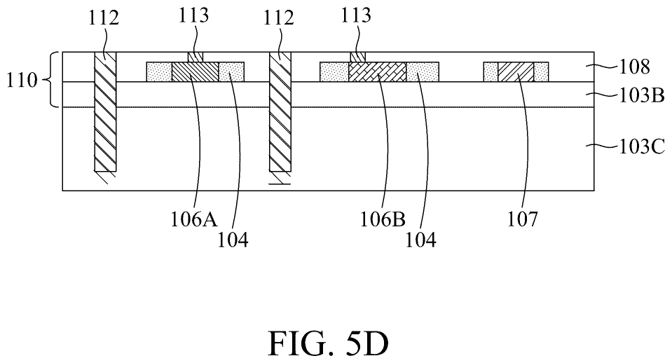

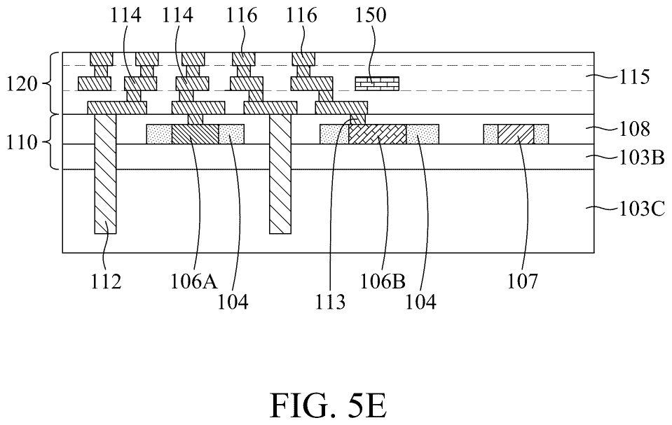

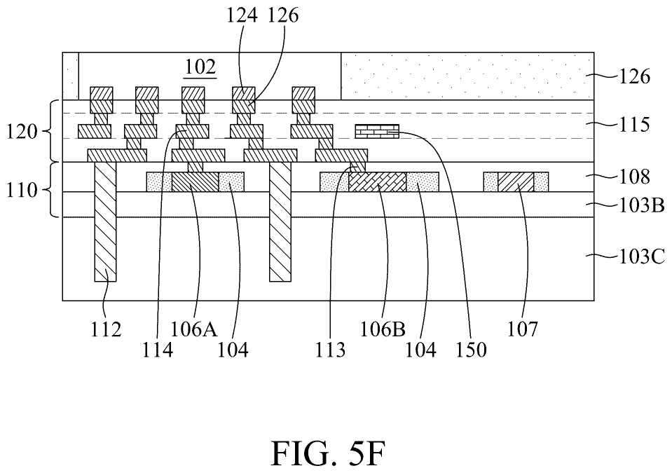

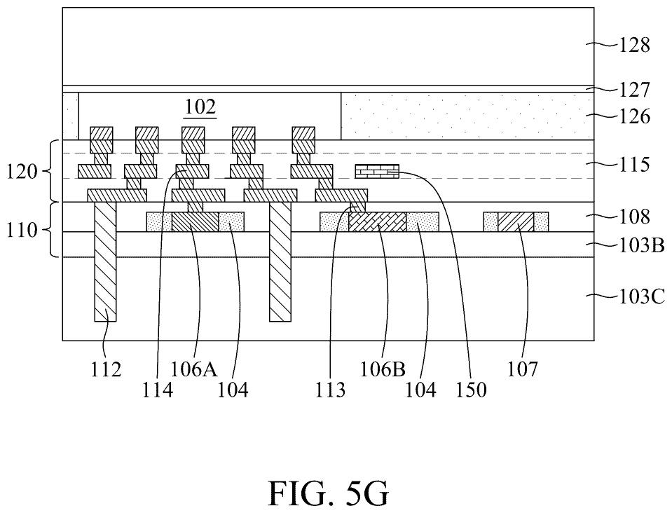

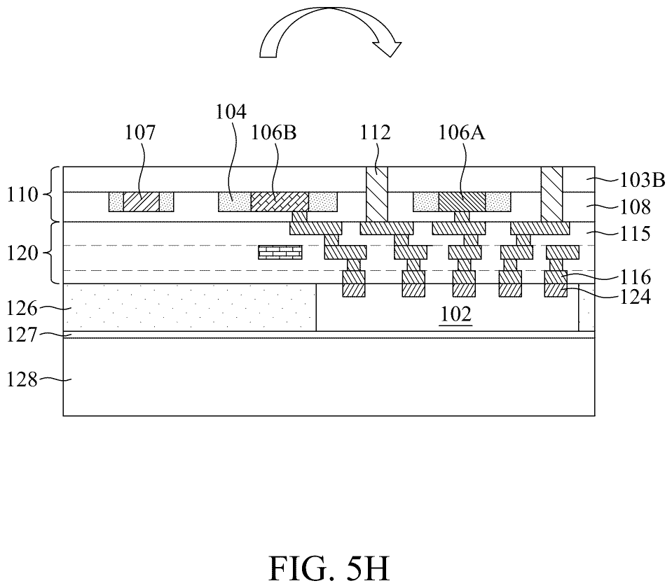

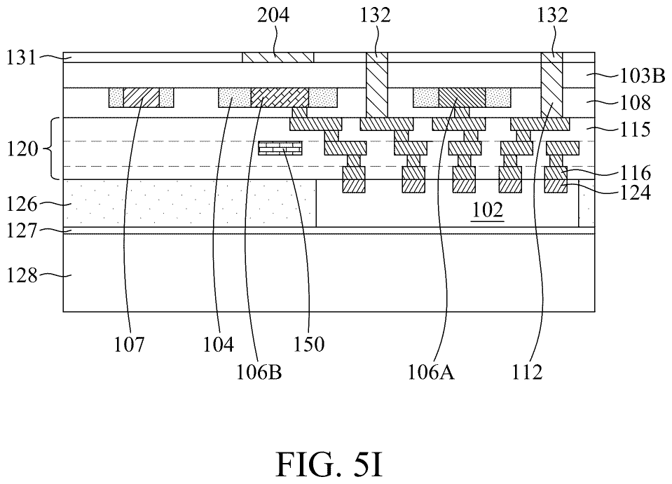

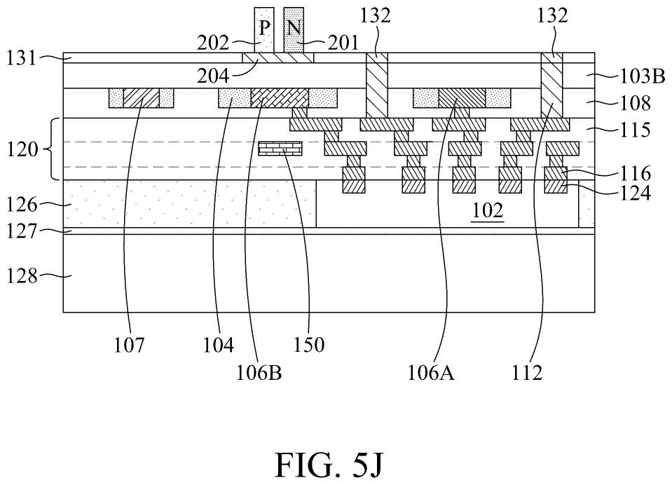

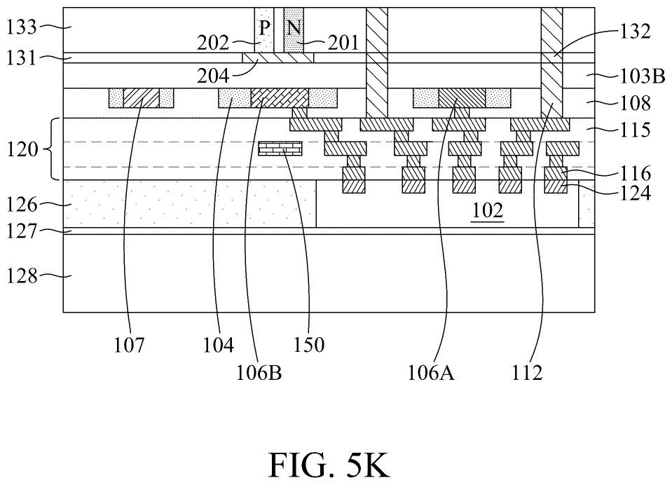

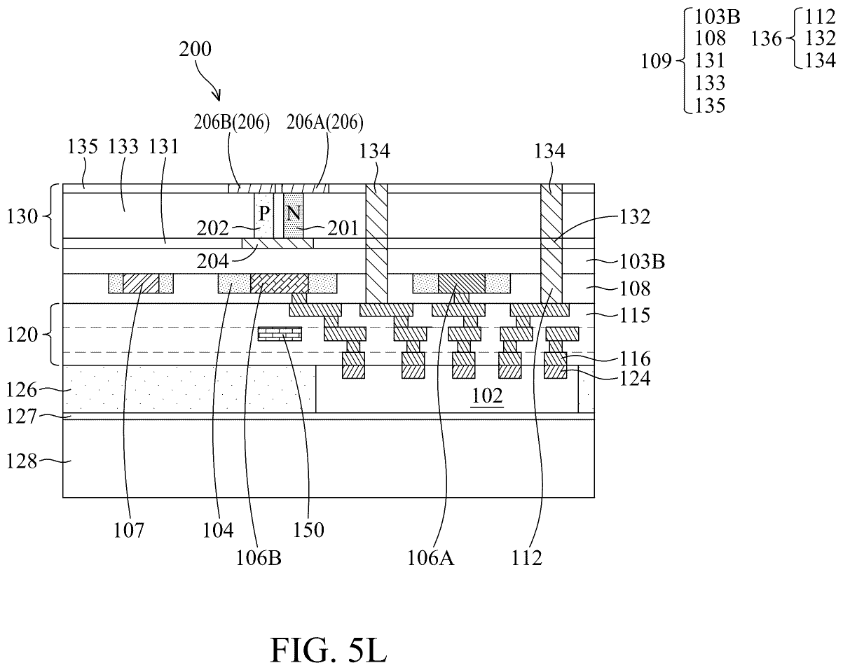

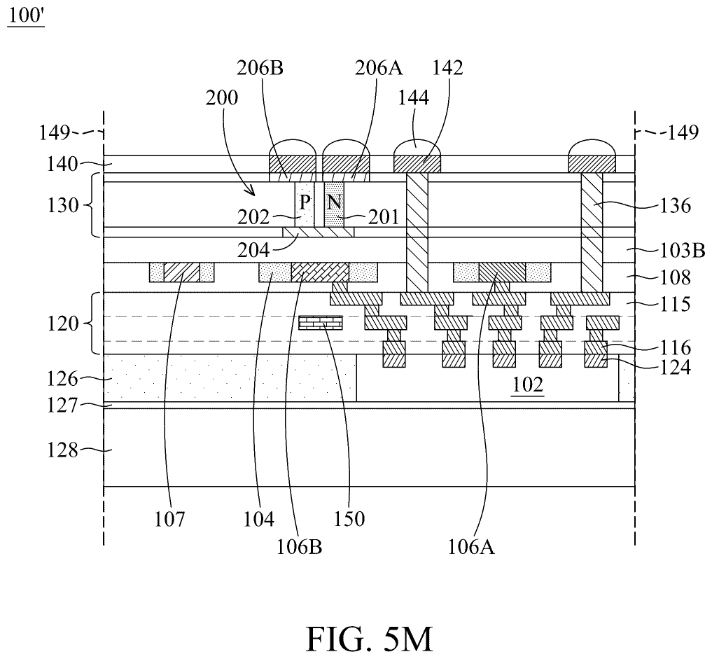

The photonic die 101 also includes conductive connectors 144 under the dielectric layers 109, which may be used to electrically connect the photonic package 100 to an external structure such as a package substrate, an interposer, a printed circuit board (PCB), or the like. The conductive connectors 144 may be electrically coupled to the conductive features 114 of the redistribution structure 120 through the vias 136. In some cases, an optional passivation layer 140 may be formed beneath the dielectric layers 109 to provide protection, and under-bump metallizations (UBMs) 142 may be formed within the passivation layer 140 to make physical and electrical contact to the vias 136. In the illustrated embodiments, some of the dielectric layers 109 below an oxide layer 103B of a buried oxide (“BOX”) substrate 103 (e.g., see FIG. 5A) and the conductive features (including conductive lines (not shown for simplicity) and vias 136) embedded therein form a second redistribution structure 130 that can provide additional interconnections and electrical routing.

Note that in the example of FIG. 1, a heater element 150 is provided within the dielectric layers 115 of the redistribution structure 120 to provide thermal energy (represented by an arrow) to a silicon photonic component (e.g., modulator 106B) below to maintain the modulator 106B operating at the desired high temperature. For example, in some cases where the modulator 106B is a micro-ring modulator (MRM), the heater element 150 would be designed to provide a high power density (e.g., several hundred watts per millimeter square) of thermal energy to maintain the modulator 106B operating at the desired high temperature, for example, around 278 degrees Celsius. The modulator 106B operating at such desired high temperature will expand, allowing optical signals within the waveguide 104 to accurately enter the modulator 106B. In this way, the thermal drift effect of the silicon photonic component (i.e., modulator 106B) can be eliminated. The heater element 150 may comprise any type of heater element that is configured to provide heat to underlying modulator 106B. For example, in some embodiments, the heater element 150 may comprise an embedded resistive coil heater with a temperature control mechanism (not shown) that is configured to control the temperature of the heater element 150 at a predetermined target temperature.

Inevitably, however, the thermal energy generated by the heater element 150 is also transferred through the heated modulator 106B to nearby components (e.g., one or more dielectric layers 109 of the second redistribution structure 130 below the oxide layer 103B), thereby creating a localized hot spot in the region HSR of the dielectric layers 109 located directly below the modulator 106B, as shown in FIG. 1. The localized hot spot within the dielectric layers 109 may pose thermal risks to the dielectric layers 109. For example, when the temperature of the material of the dielectric layers 109 in the region HSR exceed a threshold temperature (e.g., about 150 degrees Celsius), a weight loss of the dielectric layers 109 may be greater than 5%, resulting in reduced reliability. Therefore, there is a need to provide a solution to effectively remove heat from the localized hot spot region HSR of the dielectric layers 109 to reduce thermal risks of the dielectric layers 109 of the second redistribution structure 130 and improve the reliability of the entire package.

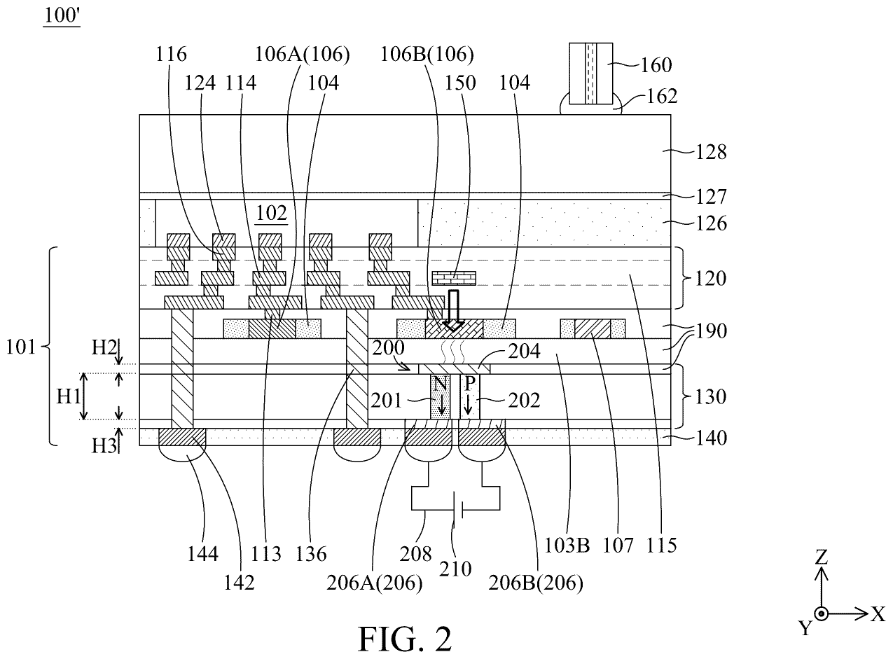

FIG. 2 is a cross-sectional view of a photonic package 100′, in accordance with some embodiments. The photonic package 100′ is similar to the photonic package 100 shown in FIG. 1, except that the photonic package 100′ further includes a thermoelectric cooling (TEC) device 200 provided (e.g., embedded) in the localized hot spot region HSR (e.g., see FIG. 1) of the dielectric layers 109 of the second redistribution structure 130 (below the oxide layer 103B) to remove or dissipate heat from the dielectric layers 109. The thermoelectric cooling device 200 is configured to cool the dielectric layers 109 (e.g., the localized hot spot region HSR) of the second redistribution structure 130 based on a thermoelectric effect such as the Peltier effect.

Referring to FIG. 2, the thermoelectric cooling device 200 includes a n-type semiconductor structure 201 extending vertically through the dielectric layers 109, a p-type semiconductor structure 202 extending vertically through the dielectric layers 109, a first conductive layer 204 (also referred to as a junction 204) coupled to the upper surface of the n-type semiconductor structure 201 and the upper surface of the p-type semiconductor structure 202, and a second conductive layer 206 having a first portion 206A (also referred to as a n-type contact 206A) coupled to the lower surface of the n-type semiconductor structure 201 and a second portion 206B (also referred to as a p-type contact 206B) coupled to the lower surface of the p-type semiconductor structure 202. In the illustrated embodiments, the first conductive layer 204 is in direct contact with the overlying oxide layer 103B, although embodiments of the disclosure are not limited thereto (for example, a dielectric layer may be interposed between the first conductive layer 204 and oxide layer 103B in other embodiments). The first portion 206A and second portion 206B of the second conductive layer 206 are electrically separated from each other and electrically coupled to two separate conductive connectors 144.

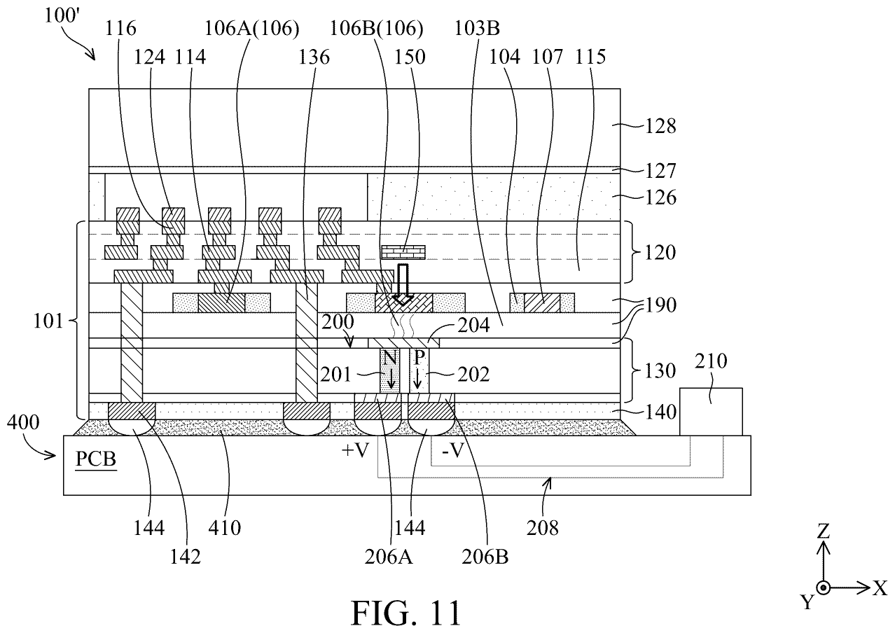

In some embodiments, a control circuit 208 electrically connects the n-type semiconductor structure 201 (through the n-type contact 206A and the respective conductive connector 144) and the p-type semiconductor structure 202 (through the p-type contact 206B and the respective conductive connector 144) to an electrical source 210 (e.g., a voltage source or a current source). In some cases where the photonic package 100′ is bonded to an external structure such as a printed circuit board (e.g., 400, see FIG. 11) via the conductive connectors 144, the control circuit 208 and the electrical source 210 may be part of the printed circuit board 400, as shown in FIG. 11.

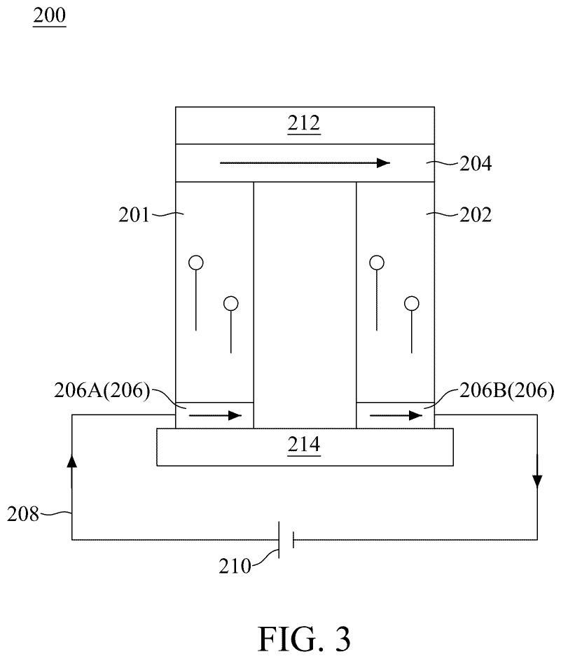

FIG. 3 is a schematic view showing the working principle of the thermoelectric cooling device 200 shown in FIG. 2, in accordance with some embodiments. As shown in FIG. 3, the thermoelectric cooling device 200 may be arranged between a cooled side 212 and a heat dissipating side 214. In the illustrated embodiments, the cooled side 212 is adjacent to a heat source (e.g., the heated modulator 106B and/or the heater element 150, see FIG. 2), and the heat dissipating side 214 is adjacent to the conductive connectors 144. The n-type semiconductor structure 201 and the p-type semiconductor structure 202 are thermally connected in parallel. In particular, first ends (e.g., the upper surfaces) of the n-type semiconductor structure 201 and the p-type semiconductor structure 202 are connected to the cooled side 212 (e.g., through the junction 204), and second ends (e.g., the lower surfaces) of the n-type semiconductor structure 201 and the p-type semiconductor structure 202 are connected to the heat dissipating side 214 (e.g., through the n-type contact 206A and the p-type contact 206B, respectively). The n-type semiconductor structure 201 and the p-type semiconductor structure 202 are electrically connected in series in that an electrically conductive path is formed from a first terminal of the electrical source 210 through the n-type semiconductor structure 201 (e.g., through the n-type contact 206A), through the p-type semiconductor structure 202 (e.g., through the junction 204), and to a second terminal of the electrical source 210 (e.g., through the p-type contact 206B).

In operation, an input is provided to the control circuit 208 by the electrical source 210. The input causes a current to flow through the control circuit 208 from the electrical source 210 to the n-type contact 206A, from the n-type contact 206A to the junction 204 through the n-type semiconductor structure 201, from the junction 204 to the p-type contact 206B through the p-type semiconductor structure 202, and from the p-type contact 206B to the electrical source 210. The n-type semiconductor structure 201 (e.g., comprising one or more n-type semiconductor material and/or one or more n-doped semiconductor material) includes an excess of electrons, and the p-type semiconductor structure 202 (e.g., comprising one or more p-type semiconductor material and/or one or more p-doped semiconductor material) includes an excess of holes (and thus, a deficit of electrons). The flow of the current through the n-type semiconductor structure 201 and the p-type semiconductor structure 202 causes the excess charge carriers (e.g., the electrons of the n-type semiconductor structure 201 and the holes of the p-type semiconductor structure 202) to migrate from the junction 204 to the respective contacts (e.g., the n-type contact 206A for the n-type semiconductor structure 201 and the p-type contact 206B for the p-type semiconductor structure 202). The migrating excess carriers transfer heat from the cooled side 212 to the heat dissipating side 214, which then dissipates heat through the conductive connectors 144 to the printed circuit board 400 (see FIG. 11) and/or additional heat sinks thereon (not shown). Accordingly, the thermoelectric cooling device 200 cools the localized hot spot region HSR (see FIG. 1) of the dielectric layers 109 of the second redistribution structure 130.

Referring back to FIG. 2, in the vertical direction (e.g., the Z-direction), both the n-type semiconductor structure 201 and the p-type semiconductor structure 202 have a first thickness H1, the junction 204 has a second thickness H2, and both the n-type contact 206A and the p-type contact 206B have a third thickness H3. In some embodiments, the first thickness H1 may be in a range between about 4 μm and about 20 μm, the second thickness H2 may be in a range between about 2 μm and about 3 μm, and the third thickness H3 may be in a range between about 1 μm and about 2 μm (i.e., the overall thickness (H1+H2+H3) of the thermoelectric cooling device 200 may be in a range between about 7 μm and about 25 μm), although other suitable thickness values for individual components of the thermoelectric cooling device 200 and/or other suitable overall thickness values of the thermoelectric cooling device 200 may be used in other embodiments.

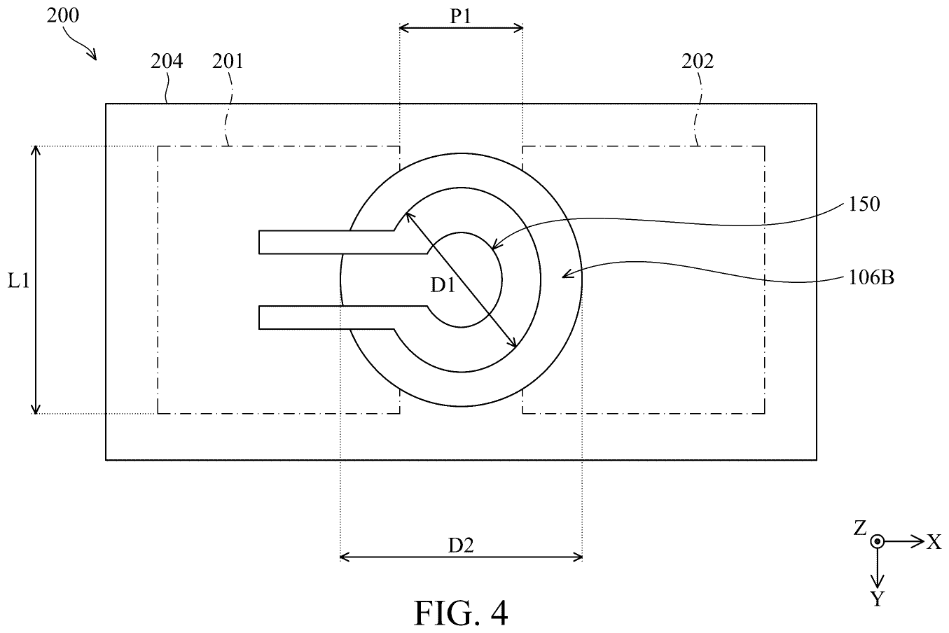

FIG. 4 is a plan view (e.g., a top-down view) showing the arrangement of a heater element 150 (e.g., an embedded resistive coil heater), a photonic component (e.g., a modulator 106B such as a micro-ring modulator), and the thermoelectric cooling device 200 shown in FIG. 2, in accordance with some embodiments. It should be noted that, for simplicity, the n-type contact 206A and the p-type contact 206B beneath the n-type semiconductor structure 201 and the p-type semiconductor structure 202 of the thermoelectric cooling device 200 are not shown. Referring to FIG. 4, the heater element 150 may be located directly over the modulator 106B (for example, the center of the circular modulator 106B may be aligned vertically with the center of the ring-shaped coil portion of heater element 150 in plan view) in some cases. The diameter D1 of the heater element 150 may be substantially equal to or less than the diameter D2 of the modulator 106B. For example, in some embodiments, the diameter D1 may be in a range between about 5 μm and about 10 μm (e.g., 5 μm), and the diameter D2 may be in a range between about 5 μm and about 10 μm (e.g., 7.5 μm), although other suitable diameter values for the heater element 150 and modulator 106B may be used in other embodiments.

In the example of FIG. 4, the thermoelectric cooling device 200 may have a substantially rectangular shape in plan view. In particular, the junction 204 at the topmost layer of the thermoelectric cooling device 200 may have a substantially rectangular shape in plan view, and the n-type semiconductor structure 201 and the p-type semiconductor structure 202 below may each have a substantially square shape in plan view. In some embodiments, the thermoelectric cooling device 200 may be located directly below the modulator 106B (for example, the center of the circular modulator 106B may be aligned vertically with the geometric center of the rectangular junction 204 in plan view). The n-type semiconductor structure 201 and the p-type semiconductor structure 202 may be located on opposite sides of the modulator 106B in plan view. For example, each of the n-type semiconductor structure 201 and the p-type semiconductor structure 202 partially overlaps the modulator 106B in plan view in some cases, as shown in FIG. 4. In some embodiments, both the n-type semiconductor structure 201 and the p-type semiconductor structure 202 may have a dimension (e.g., side length L1) in a range between about 20 μm and about 100 μm, and a pitch P1 between the n-type semiconductor structure 201 and the p-type semiconductor structure 202 may be in a range between about 2 μm and about 20 μm, although other suitable dimension values and other suitable pitch values may be used in other embodiments.

It should be noted that the shape of the components of the thermoelectric cooling device 200 and/or the arrangement and configuration of the components of the thermoelectric cooling device 200 illustrated in FIG. 4 is merely a non-limiting example, other shapes for the components and other arrangements and configurations of the components are also possible, and are fully intended to be included within the scope of the present disclosure.

FIGS. 5A to 5M illustrate cross-sectional views of intermediate steps of forming the photonic package 100′ shown in FIG. 2, in accordance with some embodiments. Referring first to FIG. 5A, a buried oxide (“BOX”) substrate 103 is provided, in accordance with some embodiments. The BOX substrate 103 includes an oxide layer 103B formed over a substrate 103C, and a silicon layer 103A formed over the oxide layer 103B. The substrate 103C may comprise a material such as glass, ceramic, dielectric, semiconductor, the like, or a combination thereof. In some embodiments, the substrate 103C is a semiconductor substrate, such as a bulk semiconductor substrate or the like, which may be doped or undoped. The substrate 103C may be a wafer, such as a silicon wafer or the like. Other substrates, such as a multi-layered or gradient substrate may also be used. In some embodiments, the semiconductor material of the substrate 103C may include silicon; germanium; a compound semiconductor including silicon carbide, gallium arsenic, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or a combination thereof. The oxide layer 103B may comprise, for example, a silicon oxide or the like.

In FIG. 5B, the silicon layer 103A is patterned to form silicon regions for waveguides 104, photonic components 106, and optical couplers 107, in accordance with some embodiments. The silicon layer 103A may be patterned using suitable photolithography and etching techniques. For example, a hard mask layer (e.g., a nitride layer, not shown) may be formed over the silicon layer 103A and patterned, in some embodiments. The pattern of the hard mask layer may then be transferred to the silicon layer 103A using one or more etching techniques, such as dry etching and/or wet etching techniques. For example, the silicon layer 103A may be etched to form recesses defining the waveguides 104, with sidewalls of the remaining unrecessed portions defining sidewalls of the waveguides 104.

The photonic components 106 may be integrated with the waveguides 104, and may be formed with the waveguides 104. The photonic components 106 may include, for example, photonic devices such as photodetectors 106A and modulators 106B in some embodiments. In some embodiments, the photodetectors 106A may be formed by, for example, partially etching regions of the waveguides 104 and growing epitaxial material on the remaining silicon of the etched regions. The waveguides 104 may be etched using acceptable photolithography and etching techniques. The epitaxial material may comprise, for example, a semiconductor material such as germanium (Ge), which may be doped or undoped. In some embodiments, an implantation process may be performed to introduce dopants within the silicon of the etched regions as part of the formation of the photodetectors 106A. The silicon of the etched regions may be doped with p-type dopants, n-type dopants, or a combination. In some embodiments, the modulators 106B may be formed by, for example, partially etching regions of the waveguides 104 and then implanting appropriate dopants within the remaining silicon of the etched regions. In some embodiments, the etched regions used for the photodetectors 106A and the etched regions used for the modulators 106B may be formed using one or more of the same photolithography or etching step. In some embodiments, the etched regions used for the photodetectors 106A and the etched regions used for the modulators 106B may be implanted using one or more of the same implantation steps.

In some embodiments, one or more optical couplers 107 may be integrated with the waveguides 104, and may be formed with the waveguides 104. The optical couplers 107 may include grating couplers and/or edge couplers. A photonic package 100′ may include a single optical coupler 107, multiple optical couplers 107, or multiple types of optical couplers 107, in some embodiments. The optical couplers 107 may be formed using acceptable photolithography and etching techniques. In some embodiments, the optical couplers 107 are formed using the same photolithography or etching steps as the waveguides 104 and/or the photonic components 106. In other embodiments, the optical couplers 107 are formed after the waveguides 104 and/or the photonic components 106 are formed.

In FIG. 5C, a dielectric layer 108 is formed on the front side (e.g., the side facing upwards in FIG. 5C) of the BOX substrate 103 to form a photonic routing structure 110, in accordance with some embodiments. The dielectric layer 108 is formed over the waveguides 104, the photonic components 106, the optical couplers 107, and the oxide layer 103B. The dielectric layer 108 may be formed of one or more layers of silicon oxide, silicon nitride, the like, or a combination thereof, and may be formed by any acceptable deposition process, such as chemical vapor deposition (CVD), physical vapor deposition (PVD), atomic layer deposition (ALD), laminating, the like, or a combination thereof. Other suitable dielectric materials formed by any acceptable process may be used.

In some embodiments, the dielectric layer 108 is then thinned using a planarization process such as a chemical-mechanical polish (CMP) process, a grinding process, or the like. In some cases, a thinner dielectric layer 108 may allow for more efficient optical coupling between an optical coupler 107 and a vertically-mounted photonic component (e.g., the optical fiber 160 shown in FIG. 2). In other embodiments, the planarization process may expose surfaces of the waveguides 104, the photonic components 106, and/or the optical couplers 107.

Due to the difference in refractive indices of the materials of the waveguides 104 and dielectric layer 108, the waveguides 104 have high internal reflections so that light is substantially confined within the waveguides 104, depending on the wavelength of the light and the refractive indices of the respective materials. In some embodiments, the refractive index of the material of the waveguides 104 is higher than the refractive index of the material of the dielectric layer 108. For example, the waveguides 104 may comprise silicon, and the dielectric layer 108 may comprise silicon oxide and/or silicon nitride.

In FIG. 5D, conductive vias 112 are formed extending into the substrate 103C, in accordance with some embodiments. The vias 112 may be formed by, for example, first forming openings (not shown separately) extending into the substrate 103C. The openings are formed extending through the dielectric layer 108 and the oxide layer 103B, and extend partially into the substrate 103C. The openings may be formed by acceptable photolithography and etching techniques. A conductive material is then formed in the openings, thereby forming vias 112. In some embodiments, a liner (not shown), such as a diffusion barrier layer (e.g., a layer made of tantalum, tantalum nitride, titanium, titanium nitride, etc.), may be formed in the openings, and may be formed using a suitable deposition process such as ALD or the like. In some embodiments, a seed layer (not shown), which may include copper or a copper alloy, may then be deposited in the openings. The conductive material of the conductive vias 112 may be formed in the openings using, for example, electroplating or electro-less plating. The conductive material may include, for example, a metal or a metal alloy such as copper, silver, gold, tungsten, cobalt, aluminum, or alloys thereof. A planarization process (e.g., a CMP process or a grinding process) may be performed to remove excess conductive material along the top surface of the dielectric layer 108, such that top surfaces of the vias 112 and the dielectric layer 108 are level.

FIG. 5D also shows the formation of contacts 113 that extend through the dielectric layer 108 and are electrically connected to the photonic components 106 (including 106A and 106B). The contacts 113 allow electrical power or electrical signals to be transmitted to the photonic components 106 and electrical signals to be transmitted from the photonic components 106. In this manner, the photonic components 106 may convert electrical signals (e.g., from an electronic die 102, see FIG. 5F) into optical signals transmitted by the waveguides 104, and/or convert optical signals from the waveguides 104 into electrical signals (e.g., that may be received by an electronic die 102). The contacts 113 may be formed before or after formation of the vias 112, and the formation of the contacts 113 and the formation of the vias 112 may share some steps such as deposition of the conductive material and/or planarization. In some embodiments, the contact may be formed by a damascene process, e.g., single damascene, dual damascene, or the like. For example, in some embodiments, openings (not shown) for the contacts 113 are first formed in the dielectric layer 108 using acceptable photolithography and etching techniques. A conductive material may then be formed in the openings, forming the contacts 113. Excess conductive material may be removed using a CMP process or the like. The conductive material of the contacts 113 may be formed of a metal or a metal alloy including aluminum, copper, tungsten, or the like, which may be the same as that of the vias 112. The contacts 113 may be formed using other techniques or materials in other embodiments.

In FIG. 5E, a (first) redistribution structure 120 is formed over the dielectric layer 108, in accordance with some embodiments. The redistribution structure 120 includes dielectric layers 115 and conductive features 114 formed in the dielectric layers 115 that provide interconnections and electrical routing. For example, the redistribution structure 120 may connect the vias 112, the contacts 113, and/or overlying devices such as electronic dies 102 (see FIG. 5F). The dielectric layers 115 may comprise one or more materials similar to those described above for the dielectric layer 108, such as a silicon oxide or a silicon nitride, or may comprise a different material. The dielectric layers 115 may be transparent to about the same wavelengths of light as the dielectric layer 108. The dielectric layers 115 may be formed using a technique similar to those described above for the dielectric layer 108 or using a different technique. The conductive features 114 may include conductive lines and vias (which may be made of the same or similar metal or metal alloy material as the vias 112 and/or contacts 113), and may be formed by a damascene process, e.g., single damascene, dual damascene, or the like.

As shown in FIG. 5E, die connectors 116 (e.g., copper pillars, copper pads, or the like) are formed in the topmost layer of the dielectric layers 115. A planarization process (e.g., a CMP process or the like) may be performed after forming the die connectors 116 such that surfaces of the die connectors 116 and the topmost dielectric layer 115 are substantially coplanar. The redistribution structure 120 may include more or fewer dielectric layers 115, conductive features 114, or die connectors 116 than shown in FIG. 5E.

In some embodiments, some regions of the redistribution structure 120 are substantially free of the conductive features 114 or conductive pads 116 in order to allow transmission of optical power or optical signals through the dielectric layers 115. For example, these metal-free regions may extend between an optical coupler 107 and an external optical fiber 160 (see FIG. 2) to allow optical power or optical signals to be coupled from the waveguides 104 into the optical fiber 160 and/or to be coupled from the optical fiber 160 into the waveguides 104.

FIG. 5E also shows the formation of a heater element 150 within a suitable dielectric layer 115 of the redistribution structure 120 and vertical alignment with a silicon photonic component (e.g., a modulator 106B). As discussed above with reference to FIG. 1, the heater element 150 is configured to provide thermal energy to underlying modulator 106B to maintain the modulator 106B operating at the desired high temperature, thereby eliminating the thermal drift effect of the silicon photonic component (e.g., modulator 106B). The heater element 150 may comprise any type of heater element that is configured to provide heat to underlying modulator 106B. In some embodiments, the heater element 150 is an embedded resistive coil heater, which may be formed together (i.e., simultaneously) with some of the conductive features 114 and may be forming using the same materials and same process steps discussed above for the conductive features 114. Other types of heater element 150 and/or other formation techniques may be used in other embodiments.

In FIG. 5F, electronic dies 102 are bonded to the redistribution structure 120, in accordance with some embodiments. Each electronic die 102 may be, for example, a semiconductor device, die, or chip that may communicate with the photonic components 106 using electrical signals. In some embodiments, the electronic die 102 includes a substrate (e.g., a semiconductor substrate such as silicon or the like, not shown separately). Electronic components (not shown), such as transistors, diodes, capacitors, resistors, etc., may be formed in and/or on the substrate and may be interconnected by an interconnect structure (not shown) to form an integrated circuit, wherein the interconnect structure is formed by, for example, metallization patterns (e.g., conductive lines and vias) in one or more dielectric layers over the substrate. The electronic die 102 further comprise pads (not shown), such as aluminum pads, to which external connections are made. The pads are on what may be referred to as the active side (or front side) of the electronic dies 102. One or more passivation layers (not shown) are formed at the front side the electronic dies 102 and on portions of the pads. Die connectors 124, such as conductive pillars (for example, comprising a metal such as copper), are formed to extend through the passivation layer(s) and are mechanically and electrically coupled to the respective pads. The electronic dies 102 can be obtained, for example, by sawing or dicing a semiconductor wafer (with several integrated circuit dies formed thereon) along scribe lines to separate the semiconductor wafer into a plurality of individual semiconductor dies.

In some embodiments, the electronic die 102 is bonded to the redistribution structure 120 using dielectric-to-dielectric bonding and/or metal-to-metal bonding (e.g., direct bonding, fusion bonding, oxide-to-oxide bonding, hybrid bonding, or the like). In such embodiments, dielectric-to-dielectric bonding may occur between the topmost dielectric layer 115 of the redistribution structure 120 and a bonding layer (not individually shown) of the electronic die 102. During the bonding, metal-to-metal bonding may also occur between the die connectors 124 of the electronic die 102 and the topmost conductive features (e.g., die connectors 116) of the redistribution structure 120.

In some embodiments, before performing the bonding process, a surface treatment is performed on the redistribution structure 120 and/or the electronic die 102. In some embodiments, the bonding surfaces of the redistribution structure 120 and/or the electronic die 102 may first be activated utilizing, for example, a dry treatment, a wet treatment, a plasma treatment, exposure to an inert gas, exposure to H₂, exposure to N₂, exposure to O₂, the like, or a combination thereof. However, any suitable activation process may be utilized. After the activation process, the redistribution structure 120 and/or the electronic die 102 may be cleaned using, e.g., a chemical rinse. The electronic die 102 is then aligned with the redistribution structure 120 and placed into physical contact with the redistribution structure 120 using, for example, a pick-and-place process. The redistribution structure 120 and the electronic die 102 may then be subjected to a thermal treatment and/or pressed against each other (e.g., by applying contact pressure) to bond the redistribution structure 120 and the electronic die 102. For example, the redistribution structure 120 and the electronic die 102 may be subjected to a pressure of about 200 kPa or less, and to a temperature in the range of about 200° C. to about 400° C. The redistribution structure 120 and the electronic die 102 may then be subjected to a temperature at or above the eutectic point of the material of the die connectors 116 and the die connectors 124 (e.g., a temperature in the range of about 150° C. to about 650° C.) to fuse the die connectors 116 and 124. In this manner, the dielectric-to-dielectric bonding and/or metal-to-metal bonding of the redistribution structure 120 and the electronic die 102 forms a bonded structure. In some embodiments, the bonded structure is baked, annealed, pressed, or otherwise treated to strengthen or finalize the bonds.

FIG. 5F also shows the formation of a dielectric layer 126 over the electronic dies 102 and the redistribution structure 120, in accordance with some embodiments. The dielectric material 126 may be formed of silicon oxide, silicon nitride, a polymer, the like, or a combination thereof, and may be formed by CVD, PVD, ALD, a spin-on-dielectric process, the like, or a combination thereof. In some embodiments, the dielectric material 126 is a gap-fill material, which may include one or more of the example materials above. In some embodiments, the dielectric material 126 may be a material (e.g., silicon oxide) that is substantially transparent to light at wavelengths suitable for transmitting optical signals or optical power between the optical coupler 107 and an external optical fiber 160 (see FIG. 2). The dielectric material 126 may be a material similar to that of the dielectric layers 115 and/or the dielectric layer 108, in some embodiments. Other dielectric materials formed by any acceptable processes may be used. The dielectric material 126 may then be planarized using a planarization process such as a CMP process, a grinding process, or the like. In some embodiments, the planarization process may expose the electronic die 102 so that the surfaces of the electronic die 122 and the dielectric material 126 are coplanar.

In FIG. 5G, an optional support 128 is attached to the above structure, in accordance with some embodiments. The support 128 is a rigid structure that is attached to the structure in order to provide structural or mechanical stability. The use of the support 128 can reduce warping or bending, which can improve the performance of the optical structures such as the waveguides 104 and/or photonic components 106. The support 128 may comprise one or more materials such as silicon (e.g., a silicon wafer or the like), silicon oxide, silicon oxynitride, silicon carbonitride, a metal, an organic core material, or the like. In some embodiments, the support 128 may be attached to the structure (e.g., to the dielectric material 126 and/or the electronic dies 102) using an adhesive layer 127. In some other embodiments, the support 128 may be attached using direct bonding (e.g., dielectric-to-dielectric bonding or fusion bonding) or another suitable technique. In some embodiments, the support 128 may be subsequently thinned using a CMP process, grinding process, or the like. Although not shown, the support 128 may also include lens structures and/or anti-reflection coating formed on its surfaces to facilitate optical coupling between the attached optical fibers 160 and the optical couplers 107 (see FIG. 2), in some embodiments.

In FIG. 5H, the resulting structure shown in FIG. 5G is flipped over and the substrate 103C is removed, in accordance with some embodiments. The structure may be attached to a temporary carrier (not shown) prior to removal of the substrate 103C, in some cases. The substrate 103C may be removed to expose the oxide layer 103B and the vias 112, in accordance with some embodiments. The substrate 103C may be removed using a CMP process, a mechanical grinding, an etching process, the like, or a combination thereof. In some embodiments, the oxide layer 103B is also thinned during removal of the substrate 103C or using a separate process step.

FIGS. 5I to 5L illustrates the formation of a second redistribution structure 130 (see FIG. 5L) over oxide layer 103B and the formation of a thermoelectric cooling (TEC) device 200 (see FIG. 5L) within the second redistribution structure 130, in accordance with some embodiment. Not that some conductive lines and interconnections within the second redistribution structure 130 are not shown in these figures for simplicity, but they are actually present. Referring first to FIG. 5I, a dielectric layer 131 is formed over the oxide layer 103B. The dielectric layer 131 may comprise, for example, a polymer such as polybenzoxazole (PBO), polyimide (PI), benzocyclobutene (BCB), or the like, and may be formed by spin coating, lamination, CVD, PVD, ALD, or the like. Conductive features (e.g., conductive lines (not shown) and vias 132) and a first conductive layer 204 of the thermoelectric cooling device 200 are then formed in the dielectric layer 131 using materials and techniques similar to those described previously for forming the vias 112. As shown in FIG. 51, the vias 132 may be vertically aligned with and contact the underlying vias 112, and the first conductive layer 204 may be vertically aligned with the underlying modulator 106B and contact the oxide layer 103B.

In FIG. 5J, an n-type semiconductor structure 201 and a p-type semiconductor structure 202 of the thermoelectric cooling device 200 are formed on and in contact with the first conductive layer 204. The n-type semiconductor structure 201 may comprise one or more n-type semiconductor material and/or one or more n-doped semiconductor material, and the p-type semiconductor structure 202 may comprise one or more p-type semiconductor material and/or one or more p-doped semiconductor material. In an illustrative embodiment, the n-type semiconductor structure 201 comprises Bi₂Te₃ and the p-type semiconductor structure 202 comprises Sb₂Te₃ as an example, although other suitable n-type and p-type semiconductor materials may be used in other embodiments. The n-type semiconductor structure 201 and the p-type semiconductor structure 202 may be formed by, for example, forming a patterned mask layer (not shown) over the first conductive layer 204, wherein the pattern of openings within the patterned mask layer corresponds to the pattern of the n-type semiconductor structure 201 and a p-type semiconductor structure 202 to be subsequently formed. An appropriate deposition process (such as sputtering) is then used to form the n-type semiconductor material and the p-type semiconductor material (as described above) in the openings of the patterned mask layer, thereby forming the n-type semiconductor structure 201 and a p-type semiconductor structure 202 on the first conductive layer 204. After formation of the n-type semiconductor structure 201 and the p-type semiconductor structure 202, the patterned mask layer may be removed an ashing process or other acceptable etching processes, in some embodiments. Other suitable processes for forming the n-type semiconductor structure 201 and p-type semiconductor structure 202 may be used in other embodiments.

In FIG. 5K, a dielectric layer 133 is formed over the dielectric layer 131, the first conductive layer 204, the vias 132, the n-type semiconductor structure 201, and the p-type semiconductor structure 202 using materials and techniques similar to those described previously for forming the dielectric layer 131, in accordance with some embodiments. The dielectric layer 133 is then thinned using a planarization process such as a CMP process, a grinding process, or the like, until the top surfaces of the n-type semiconductor structure 201 and the p-type semiconductor structure 202 are revealed.

In FIG. 5L, a dielectric layer 135 is formed on the dielectric layer 133, the n-type semiconductor structure 201, and the p-type semiconductor structure 202 using materials and techniques similar to those described previously for forming the dielectric layer 131, in accordance with some embodiments. Vias 134 extending through the dielectric layer 135 and the dielectric layer 133 to contact the underlying vias 132 are then formed using materials and techniques similar to those described previously for forming the vias 112, in accordance with some embodiments. In the description herein, the via 134, the via 132 and the via 112 that are stacked and connected to each other may be collectively referred to as a via 136 (see also FIG. 2), which extends through the dielectric layer 108, the oxide layer 103B, the dielectric layer 131, the dielectric layer 133 and the dielectric layer 135 (these layers may be collectively referred to herein as one or more dielectric layers 109, as shown in FIG. 2). Some of the dielectric layers 109 (e.g., 131, 133 and 135) over the oxide layer 103B and the conductive features (including conductive lines (not shown) and vias 136) embedded therein form the second redistribution structure 130 (see also FIG. 2).

FIG. 5L also shows the formation of a second conductive layer 206 of the thermoelectric cooling device 200 in the dielectric layer 135. The second conductive layer 206 may be formed in the dielectric layer 135 using materials and techniques similar to those described previously for forming the vias 112, in accordance with some embodiments. In some embodiments, the second conductive layer 206 of the thermoelectric cooling device 200 may be formed before or after formation of the vias 134. The second conductive layer 206 may include a first portion 206A (i.e., n-type contact 206A) in contact with the n-type semiconductor structure 201 and a second portion 206B (i.e., p-type contact 206B) in contact with the p-type semiconductor structure 202.

The first conductive layer 204, the n-type semiconductor structure 201, the p-type semiconductor structure 202, and the first portion 206A and second portion 206B of the second conductive layer 206 within the dielectric layers 131, 133 and 135 (which may be made of polyimide and therefore may also be referred to polyimide layers in some case) constitute the thermoelectric cooling device 200. As discussed above, the thermoelectric cooling device 200 is compatible with existing semiconductor manufacturing processes and can be fabricated concurrently with the fabrication of the second redistribution structure 130. For example, the first conductive layer 204 and the second conductive layer 206 of the thermoelectric cooling device 200 may be formed in the same steps as the formation of the conductive features (e.g., conductive lines (not shown) and the vias 136) of the second redistribution structure 130, in some embodiments.

In FIG. 5M, conductive connectors 144 are formed over the vias 136, in accordance with some embodiments. In some embodiments, an optional passivation layer 140 is formed over the second redistribution structure 130 before forming the conductive connectors 144. The passivation layer 140 may comprise, for example, a polymer such as PBO, PI, BCB, or the like, and may be formed by spin coating, lamination, CVD, PVD, ALD, or the like. In some embodiments, under-bump metallizations (UBMs) 142 may be formed within the passivation layer 140 to make physical and electrical contact to the vias 136. The UBMs 142 may be formed of one or more suitable conductive materials using a suitable process, such as plating. The conductive connectors 144 are then formed on the UBMs 142 using a suitable process, such as plating, printing, solder transfer, ball placement, or the like, in accordance with some embodiments. The conductive connectors 144 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 144 may include a conductive material such as solder, copper, aluminum, gold, nickel, silver, palladium, tin, the like, or a combination thereof.

Still referring to FIG. 5M, a singulation process is then performed by, for example, sawing along scribe lines 149 of the package structure to separate the multiple photonic packages within the package structure into individual photonic packages 100′, such as the individual photonic package 100′ shown in FIG. 2. In some cases, the package structure may be flipped over and attached to a temporary carrier (not shown) prior to the singulation process. A de-bonding process may then be performed to de-bond or remove the carrier from the photonic packages 100′ after the singulation process. The carrier may be removed by any acceptable process, such as an etching process, a CMP process, a grinding process, the like, or other acceptable removal processes. Although not shown, in some cases, optical fibers 160 (e.g., see FIG. 2) may be attached to the supports 128 of the photonic packages 100′ within the package structure before performing the singulation process.

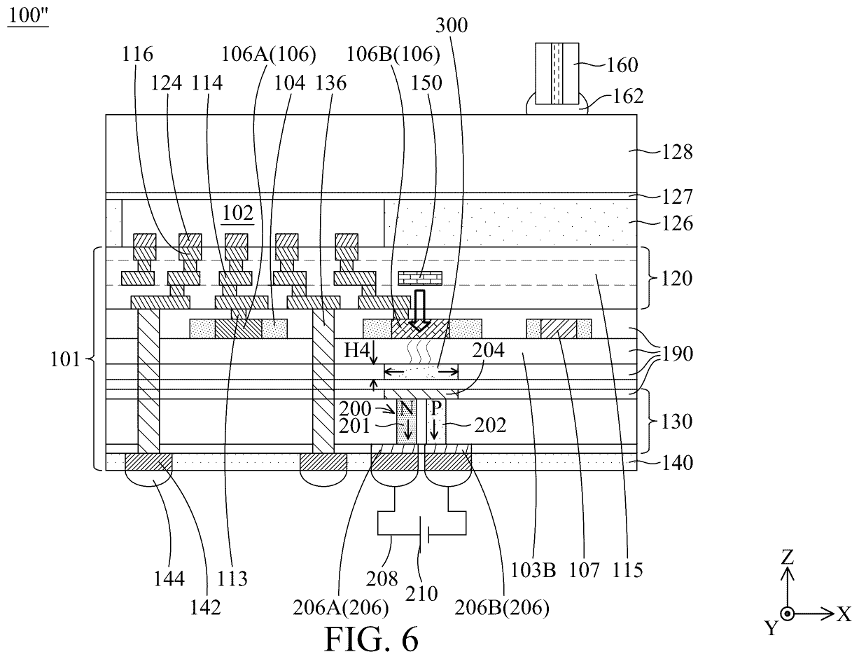

FIG. 6 is a cross-sectional view of a photonic package 100″, in accordance with some embodiments. The photonic package 100″ is similar to the photonic package 100′ shown in FIG. 2, except that the photonic package 100″ further includes a heat spreader 300 (e.g., a copper (Cu) spreader) provided (e.g., embedded) within the localized hot spot region HSR (e.g., see FIG. 1) of the dielectric layers 109 of the second redistribution structure 130 (below the oxide layer 103B) and arranged vertically between the heated modulator 106B and the thermoelectric cooling device 200. The heat spreader 300 is configured to allow heat to spread rapidly across the heat spreader 300 from a localized hot spot (e.g., located directly below the heated modulator 106B) in horizontal directions (e.g., in the X-Y plane), and then the heat is transferred by the thermoelectric cooling device 200 from the cooled side (e.g., adjacent to the heat spreader 300) to the heat dissipating side, which then dissipates heat through the conductive connectors 144 to the printed circuit board and/or additional heat sinks thereon (not shown). Accordingly, the cooling efficiency of the thermoelectric cooling device 200 is improved through the heat spreader 300. The heat spreader 300 may be formed using materials and techniques similar to those described previously for forming the vias 112, in accordance with some embodiments.

In some embodiments, the heat spreader 300 has a thickness H4 (e.g., in a range between about 5 μm and about 10 μm) that is greater than the thickness H2 (see FIG. 2) of the first conductive layer 204 of the thermoelectric cooling device 200 to obtain better horizontal heat dissipation capabilities. In some embodiments, the heat spreader 300 is disposed within the topmost dielectric layer 109 of the second redistribution structure 130 and contacts the oxide layer 103B. In some embodiments, a dielectric layer 109 is inserted between the heat spreader 300 and the first conductive layer 204 of the thermoelectric cooling device 200 to prevent the conductive lines (not shown) at the same layer as the heat spreader 300 from forming a short circuit with the first conductive layer 204. In other embodiments, the dielectric layer 109 between the heat spreader 300 and the first conductive layer 204 may be omitted if there is no short circuit issue.

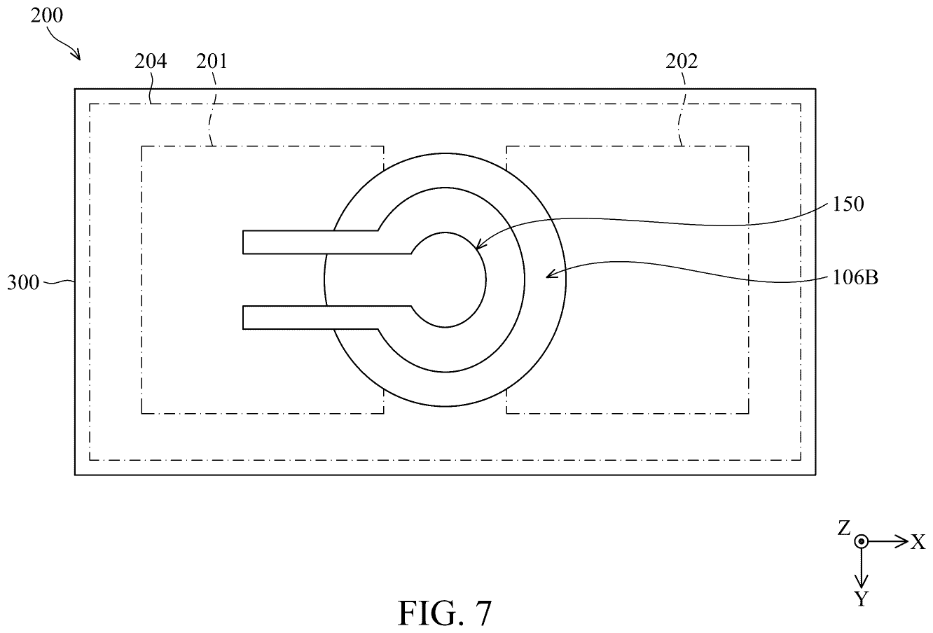

FIG. 7 is a plan view (e.g., a top-down view) showing the arrangement of a heater element 150 (e.g., an embedded resistive coil heater), a photonic component (e.g., a modulator 106B such as a micro-ring modulator), a heat spreader 300, and the thermoelectric cooling device 200 shown in FIG. 6, in accordance with some embodiments. The arrangement of the heater element 150, the modulator 106B, and the thermoelectric cooling device 200 shown in FIG. 7 may be the same as that of the heater element 150, the modulator 106B, and the thermoelectric cooling device 200 shown in

FIG. 4, so the details are not repeated here. In the example of FIG. 7, the heat spreader 300 may have a substantially rectangular shape in plan view, and may be located directly over junction 204 of the thermoelectric cooling device 200 (for example, the geometric center of the rectangular heat spreader 300 may be aligned vertically with the geometric center of the rectangular junction 204 in plan view) in some case. The size (i.e., the area in the X-Y plane) of the heat spreader 300 may be equal to or larger than that of the junction 204 of the thermoelectric cooling device 200. Other shapes and/or other arrangements of the heat spreader 300 are also possible, and are fully intended to be included within the scope of the present disclosure.

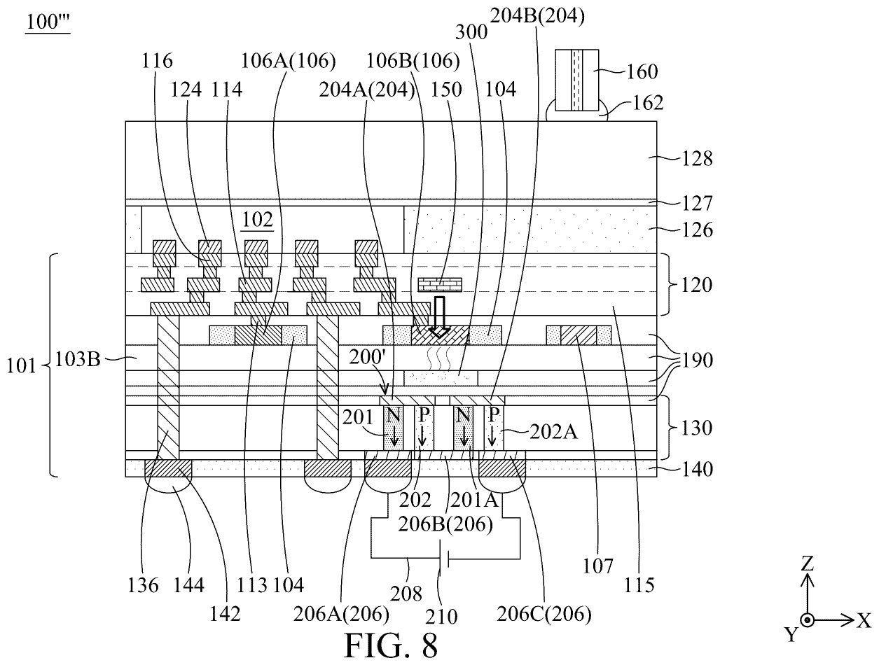

FIG. 8 is a cross-sectional view of a photonic package 100″′, in accordance with some embodiments. The photonic package 100″′ is similar to the photonic package 100″ shown in FIG. 6, except that the thermoelectric cooling device 200 is replaced by a thermoelectric cooling device 200′. The thermoelectric cooling device 200′ includes a first n-type semiconductor structure 201, a first p-type semiconductor structure 202, a second n-type semiconductor structure 201A, a second p-type semiconductor structure 202A, a first conductive layer 204 having a first portion 204A (also referred to as a first junction 204A) coupled to the upper surface of the first n-type semiconductor structure 201 and the upper surface of the first p-type semiconductor structure 202 and a second portion 204B (also referred to as a second junction 204B) coupled to the upper surface of the second n-type semiconductor structure 201A and the upper surface of the second p-type semiconductor structure 202A, and a second conductive layer 206 having a first portion 206A (also referred to as a n-type contact 206A) coupled to the lower surface of the first n-type semiconductor structure 201, a second portion 206B (also referred to as a third junction 206B) coupled to the lower surface of the first p-type semiconductor structure 202 and the lower surface of the second n-type semiconductor structure 201A, and a third portion 206C (also referred to as a p-type contact 206C) coupled to the lower surface of the second p-type semiconductor structure 202A. The first portion 204A and second portion 204B of the first conductive layer 204 are electrically separated from each other. The first portion 206A, second portion 206B, and third portion 206C of the second conductive layer 206 are electrically separated from each other, and the first portion 206A (i.e., n-type contact 206A) and the third portion 206C (i.e., p-type contact 206C) are electrically coupled to two separate conductive connectors 144.

In the illustrated embodiments, the first n-type semiconductor structure 201, the first p-type semiconductor structure 202, the first portion 204A of the first conductive layer 204, and the first portion 206A of the second conductive layer 206 form a first thermoelectric device. The second n-type semiconductor structure 201A, the second p-type semiconductor structure 202A, the second portion 204B of the first conductive layer 204, and the second portion 206B and third portion 206C of the second conductive layer 206 form a second thermoelectric device. The first thermoelectric device and the second thermoelectric device are connected in series to form a serial connected thermoelectric cooling device 200′, which has improved cooling efficiency compared to the thermoelectric cooling device 200 shown in FIG. 2 or 6. In cases where the heat spreader 300 (e.g., a Cu spreader) is disposed vertically between the heated modulator 106B and the thermoelectric cooling device 200′, each of the first portion 204A and second portion 204B of the first conductive layer 204 partially overlaps the heat spreader 300 in the vertical direction (e.g., the Z-direction), such that the first thermoelectric device and the second thermoelectric device of the thermoelectric cooling device 200′ can be thermally coupled to the heat spreader 300.

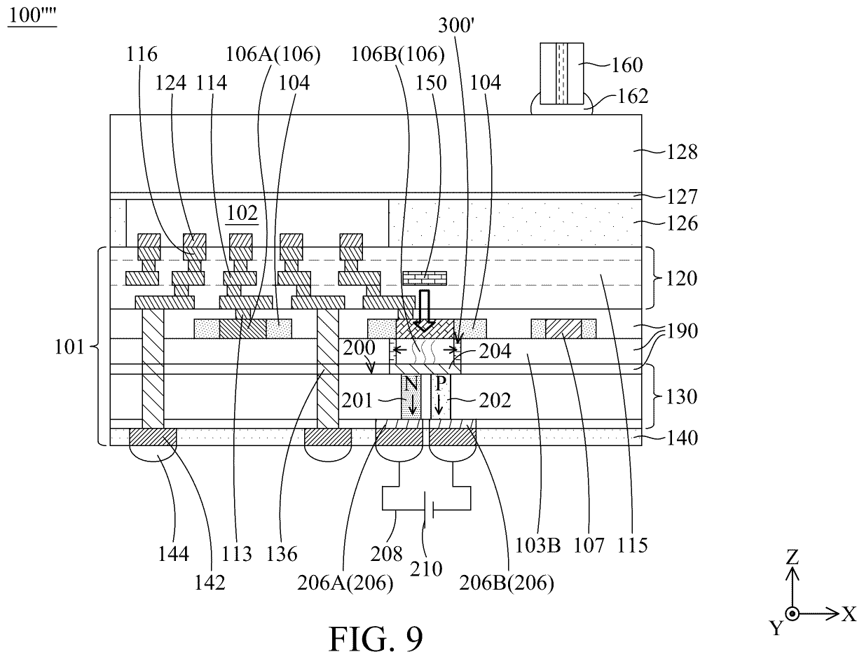

FIG. 9 is a cross-sectional view of a photonic package 100″″, in accordance with some embodiments. The photonic package 100″″ is similar to the photonic package 100′ shown in FIG. 2, except that the photonic package 100″″ further includes a heat spreader 300′ (e.g., a Cu spreader) provided (e.g., embedded) within the oxide layer 103B and arranged vertically between the heated modulator 106B and the thermoelectric cooling device 200. In some embodiments, the heat spreader 300′ extends through the entire thickness of the oxide layer 103B or extends from the bottom surface of the oxide layer 103B to a depth below the top surface of the oxide layer 103B (i.e., not exposed from the top surface of the oxide layer 103B). It should be noted that although in the example of FIG. 9 the thermoelectric cooling device 200 (e.g., the first conductive layer 204) is depicted in direct contact with the oxide layer 103B (and the heat spreader 300′), the thermoelectric cooling device 200 (e.g., the first conductive layer 204) may be separated from the oxide layer 103B (and the heat spreader 300′) by a dielectric layer 109 in other embodiments. In addition, the heat spreader 300′ in the example of FIG. 9 has a hollow ring structure different from the heat spreader 300 described above.

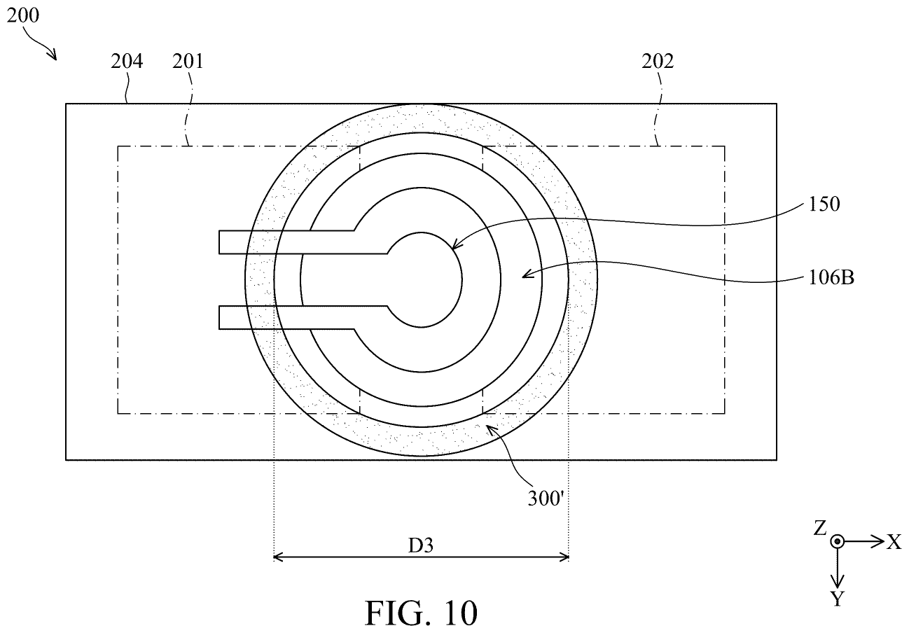

FIG. 10 is a plan view (e.g., a top-down view) showing the arrangement of a heater element 150 (e.g., an embedded resistive coil heater), a photonic component (e.g., a modulator 106B such as a micro-ring modulator), a heat spreader 300′, and the thermoelectric cooling device shown 200 in FIG. 9, in accordance with some embodiments. The arrangement of the heater element 150, the modulator 106B, and the thermoelectric cooling device 200 shown in FIG. 10 may be the same as that of the heater element 150, the modulator 106B, and the thermoelectric cooling device 200 shown in FIG. 4, so the details are not repeated here. In the example of FIG. 10, the heat spreader 300′ is located directly over the modulator 106B (for example, the center of the circular modulator 106B may be aligned vertically with the center of the ring-shaped heat spreader 300′ in plan view) in some cases. In some embodiments, the inner diameter D3 of the ring-shaped heat spreader 300′ may be slightly larger than the diameter D2 (e.g., see FIG. 4) of the modulator 106B, for example, in a range between about be in a range between about 6 μm and about 10 μm (e.g., 8 μm), such that the heat spreader 300′ and the modulator 106B may not contact each other. This prevents the modulator 106B from forming a short circuit with the conductive lines or interconnections of the second redistribution structure 130 (or the thermoelectric cooling device 200) through the heat spreader 300′.

The heat spreader 300′ may be formed within the oxide layer 103B using materials and techniques similar to those described previously for forming the vias 112, in accordance with some embodiments. For example, in some cases, before forming the second redistribution structure 130 over the oxide layer 103B (e.g., in the step illustrated in FIG. 5H), a patterned mask layer (not shown) may be formed the oxide layer 103B, wherein the pattern of openings within the patterned mask layer corresponds to the pattern of the heat spreader 300′ to be formed. The pattern of the mask layer may then be transferred to the oxide layer 103B using one or more etching techniques, such as dry etching and/or wet etching techniques. A conductive material (e.g., Cu) is then formed in the openings of the oxide layer 103B, thereby forming the heat spreader 300′. A planarization process (e.g., a CMP process or a grinding process) may be performed to remove excess conductive material along the top surface of the oxide layer 103B, such that top surfaces (i.e., the bottom surfaces illustrated in FIG. 9) of the heat spreader 300′ and the oxide layer 103B are level.

Similarly, the heat spreader 300′ allows heat to spread rapidly across the heat spreader 300′ from a localized hot spot (e.g., located directly below the heated modulator 106B) in horizontal directions (e.g., in the X-Y plane), and then the heat is transferred by the thermoelectric cooling device 200 from the cooled side (e.g., adjacent to the heat spreader 300′) to the heat dissipating side, which then dissipates heat through the conductive connectors 144 to the printed circuit board and/or additional heat sinks thereon (not shown). Accordingly, the cooling efficiency of the thermoelectric cooling device 200 is improved through the heat spreader 300′.

In some other embodiments, the heat spreader 300′ embedded in the oxide layer 103B may adopt the same shape and structure as the heat spreader 300 shown in FIGS. 6 and 7.

FIG. 11 is a cross-sectional view of a semiconductor package that includes the photonic package 100′ shown in FIG. 2 mounted on a printed circuit board (PCB) 400, in accordance with some embodiments. The photonic package 100′ is bonded to the PCB 400 using the conductive connectors 144 in some cases. An underfill layer 410 may be formed in the gap between the photonic package 100′ and the PCB 400 to surround and protect the conductive connectors 144 and enhance the connection between the photonic package 100′ and the PCB 400. The underfill material of the underfill layer 410 may, for example, include an epoxy, a resin, a filler material, a stress release agent (SRA), an adhesion promoter, another suitable material, or a combination thereof. In some embodiments, the underfill material may be applied in liquid form and then cured through a reflow process to form the underfill layer 410. It should also be understood that because the thermoelectric cooling device 200 can effectively transfer heat from the dielectric layers 109 adjacent the bottom of the photonic package 100′ to the PCB 400 (and then the heat can be dissipated through the PCB 400), it can also reduce the thermal risks to adjacent underfill layer 410 caused by heat build-up in the dielectric layers 109. Accordingly, the reliability of the underfill layer 410 and the entire semiconductor package is further improved.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, while the present disclosure is described using embodiments in which thermoelectric cooling devices are disposed within localized hot spot regions of some dielectric layers located directly below heated modulators, embodiments are expressly contemplated herein in which thermoelectric cooling devices are disposed within localized hot spot regions of some dielectric layers located directly below other types of heated silicon photonic components. In addition, while in the above embodiments the thermoelectric cooling device is arranged in the localized hot spot region of some dielectric layers located directly below the heated photonic component, the thermoelectric cooling device can also be placed in the vicinity of the localized hot spot region of the dielectric layers (e.g., not located directly below the heated photonic component) as long as it can effectively cool the localized hot spot region of the dielectric layers.

Embodiments of the present disclosure discussed herein may have advantages. By providing (e.g., embedding) a thermoelectric cooling device in some dielectric layers located below the heated silicon photonic component (e.g., modulator), the heat in the dielectric layers (e.g., the localized hot spot region) can be effectively removed and dissipated, thereby reducing thermal risks to the dielectric layers. As a result, the reliability of the dielectric layers and the entire package is improved. In addition, the thermoelectric cooling device is compatible with existing semiconductor manufacturing processes and can be fabricated concurrently with the fabrication of the redistribution structure of the photonic package.

In accordance with some embodiments, a semiconductor package is provided. The semiconductor package includes an oxide layer, and a waveguide and a photonic component located on a first side of the oxide layer. The semiconductor package also includes a heater element adjacent to the photonic component and configured to provide thermal energy to the photonic component. The semiconductor package also includes a redistribution structure located on a second side of the oxide layer opposite the first side. The redistribution structure includes a plurality of dielectric layers and conductive features in the dielectric layers. In addition, the semiconductor package includes a thermoelectric cooling device embedded in the dielectric layers of the redistribution structure and located directly below the photonic component.

In accordance with some embodiments, a semiconductor package is provided. The semiconductor package includes an oxide layer, and a photonic component located on a first side of the oxide layer. The semiconductor package also includes a heater element adjacent to the photonic component and configured to provide thermal energy to the photonic component. The semiconductor package also includes a redistribution structure located on a second side of the oxide layer opposite the first side. The redistribution structure includes a plurality of dielectric layers and conductive features in the dielectric layers. In addition, the semiconductor package includes a thermoelectric cooling device embedded in the dielectric layers of the redistribution structure. The thermal energy provided by the heater element is also transferred through the photonic component to the dielectric layers, causing a localized hot spot occurring in a region of the dielectric layers located directly below the photonic component. The thermoelectric cooling device is arranged directly in the region of the dielectric layers or adjacent to the region of the dielectric layers.

In accordance with some embodiments, a method of forming a semiconductor package is provided. The method includes forming a waveguide and a photonic component on a first side of the oxide layer. The method also includes forming a first redistribution structure over the waveguide and the photonic component, wherein the first redistribution structure includes a plurality of first dielectric layers and first conductive features in the first dielectric layers. The method also includes providing a heater element in one of the plurality of first dielectric layers of the first redistribution structure to provide thermal energy to the photonic component. The method also includes bonding an electronic die to the first redistribution structure, wherein the electronic die is electrically connected to the photonic component through the first conductive features. The method also includes forming a second redistribution structure on a second side of the oxide layer opposite the first side, wherein the second redistribution structure includes a plurality of second dielectric layers and second conductive features in the second dielectric layers. In addition, the method includes providing a thermoelectric cooling device in the second dielectric layers of the second redistribution structure, wherein the thermoelectric cooling device is located directly below the photonic component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an oxide layer;
a waveguide and a photonic component located on a first side of the oxide layer;
a heater element adjacent to the photonic component;
a redistribution structure located on a second side of the oxide layer opposite the first side, wherein the redistribution structure comprises a plurality of dielectric layers and conductive features in the plurality of dielectric layers; and
a thermoelectric cooling device embedded in the plurality of dielectric layers of the redistribution structure and located directly below the photonic component.

2. The semiconductor package as claimed in claim 1, wherein the photonic component is a silicon photonic component containing silicon.

3. The semiconductor package as claimed in claim 2, wherein the photonic component is a modulator and wherein the heater element is configured to provide thermal energy to the photonic component.

4. The semiconductor package as claimed in claim 1, wherein the thermoelectric cooling device comprises:
a n-type semiconductor structure and a p-type semiconductor structure extending vertically through at least some of the plurality of dielectric layers;
a first conductive layer coupled to an upper surface of the n-type semiconductor structure and an upper surface of the p-type semiconductor structure; and
a second conductive layer having a first portion coupled to a lower surface of the n-type semiconductor structure and a second portion coupled to a lower surface of the p-type semiconductor structure.

5. The semiconductor package as claimed in claim 4, further comprising a plurality of conductive connectors located under the redistribution structure, wherein the first portion and the second portion of the second conductive layer are electrically separated from each other and electrically coupled to two of the plurality of conductive connectors.

6. The semiconductor package as claimed in claim 4, wherein the first conductive layer is in direct contact with the oxide layer, and the first conductive layer overlaps the photonic component in a plan view.

7. The semiconductor package as claimed in claim 4, further comprising a heat spreader arranged vertically between the photonic component and the first conductive layer of the thermoelectric cooling device.

8. The semiconductor package as claimed in claim 7, wherein the heat spreader is embedded in a topmost dielectric layer of the plurality of dielectric layers of the redistribution structure and in direct contact with the oxide layer.

9. The semiconductor package as claimed in claim 7, wherein the heat spreader is embedded in the oxide layer and separated from the photonic component by a portion of the oxide layer.

10. The semiconductor package as claimed in claim 9, wherein the heat spreader has a hollow ring structure, and an inner diameter of the hollow ring structure is larger than a diameter of the photonic component.

11. The semiconductor package as claimed in claim 1, wherein the thermoelectric cooling device comprises:
a first n-type semiconductor structure, a first p-type semiconductor structure, a second n-type semiconductor structure and a second p-type semiconductor structure extending vertically through at least some of the plurality of dielectric layers;
a first conductive layer having a first portion coupled to an upper surface of the first n-type semiconductor structure and an upper surface of the first p-type semiconductor structure, and a second portion coupled to an upper surface of the second n-type semiconductor structure and an upper surface of the second p-type semiconductor structure; and
a second conductive layer having a first portion coupled to a lower surface of the first n-type semiconductor structure, a second portion coupled to a lower surface of the first p-type semiconductor structure and a lower surface of the second n-type semiconductor structure, and a third portion coupled to a lower surface of the second p-type semiconductor structure,
wherein the first portion and the second portion of the first conductive layer are electrically separated from each other, and the first portion, the second portion and the third portion of the second conductive layer are electrically separated from each other.

12. The semiconductor package as claimed in claim 1, further comprising:
an interconnect structure located over the waveguide and the photonic component on the oxide layer; and
an electronic die located over the interconnect structure and interconnected with the photonic component through the interconnect structure,
wherein the heater element is embedded in a dielectric layer of the interconnect structure.

13. A semiconductor package, comprising:
an oxide layer;
a photonic component located on a first side of the oxide layer;
a heater element adjacent to the photonic component;
a redistribution structure located on a second side of the oxide layer opposite the first side, wherein the redistribution structure comprises a plurality of dielectric layers and conductive features in the plurality of dielectric layers; and
a thermoelectric cooling device embedded in the plurality of dielectric layers of the redistribution structure, and wherein the thermoelectric cooling device is arranged directly in a region of the plurality of dielectric layers located directly below the photonic component or adjacent to the region of the plurality of dielectric layers located directly below the photonic component.

14. The semiconductor package as claimed in claim 13, further comprising:
a printed circuit board electrically connected to the redistribution structure and the thermoelectric cooling device through a plurality of conductive connectors located under the redistribution structure; and
an underfill layer formed in a gap between the redistribution structure and the printed circuit board to surround the plurality of conductive connectors.

15. The semiconductor package as claimed in claim 13, where the heater element is configured to provide thermal energy to the photonic component, and wherein the thermal energy provided by the heater element is also transferred through the photonic component to the plurality of dielectric layers, causing a localized hot spot occurring in a region of the plurality of dielectric layers located directly below the photonic component.

16. A method of forming a semiconductor package, comprising:
forming a waveguide and a photonic component on a first side of an oxide layer;
forming a first redistribution structure over the waveguide and the photonic component, wherein the first redistribution structure comprises a plurality of first dielectric layers and first conductive features in the plurality of first dielectric layers;
providing a heater element in one of the plurality of first dielectric layers of the first redistribution structure;
bonding an electronic die to the first redistribution structure, wherein the electronic die is electrically connected to the photonic component through the first conductive features;
forming a second redistribution structure on a second side of the oxide layer opposite the first side, wherein the second redistribution structure comprises a plurality of second dielectric layers and second conductive features in the plurality of second dielectric layers; and
providing a thermoelectric cooling device in the plurality of second dielectric layers of the second redistribution structure, wherein the thermoelectric cooling device is located directly below the photonic component.

17. The method as claimed in claim 16, wherein providing the thermoelectric cooling device comprises:
forming a n-type semiconductor structure and a p-type semiconductor structure extending vertically through at least some of the plurality of second dielectric layers;
forming a first conductive layer coupled to an upper surface of the n-type semiconductor structure and an upper surface of the p-type semiconductor structure; and
forming a second conductive layer having a first portion coupled to a lower surface of the n-type semiconductor structure and a second portion coupled to a lower surface of the p-type semiconductor structure, wherein the first portion and the second portion of the second conductive layer are electrically separated from each other, and the first conductive layer is closer to the oxide layer than the second conductive layer.

18. The method as claimed in claim 17, further comprising:
providing a first conductive connector coupled to the first portion of the second conductive layer; and
providing a second conductive connector coupled to the second portion of the second conductive layer.

19. The method as claimed in claim 17, wherein the n-type semiconductor structure, the p-type semiconductor structure, the first conductive layer, and the second conductive layer of the thermoelectric cooling device are formed during formation of the second redistribution structure.

20. The method as claimed in claim 17, further comprising:
providing a heat spreader in a topmost dielectric layer of the plurality of second dielectric layers of the second redistribution structure and arranged vertically between the photonic component and the first conductive layer of the thermoelectric cooling device; or
providing a heat spreader in the oxide layer and arranged vertically between the photonic component and the first conductive layer of the thermoelectric cooling device, wherein the heat spreader is electrically isolated from the photonic component through a portion of the oxide layer.
